(19) United States
(12) Patent Application Publication
(10) Pub. No.: US 2009/0221106 A1
(43) Pub. Date: Sep. 3, 2009

(54) Article and method for color and intensity balanced solid state light sources

(75) Inventors: Scott M. Zimmerman, Basking Ridge, NJ (US); Karl W. Beeson, Princeton, NJ (US); William R. Livesay, San Diego, CA (US); Richard L. Ross, Del Mar, CA (US)

Correspondence Address: Goldeneye, Inc.;Suite 233, 9747 Businesspark Avenue, San Diego, CA, 92131, US

(73) Assignee: Goldeneye, Inc.

(21) Appl. No.: 12/380,444

(22) Filed: Feb. 27, 2009

Related U.S. Application Data
(60) Provisional application No. 61/067,936, filed on Mar. 1, 2008.

(51) Int. Cl. H01L 21/00

(52) U.S. Cl. 438/29; 257/E21.002

(57) ABSTRACT

Subtractive and/or additive techniques can adjust both color and/or intensity in solid wavelength conversion materials.

### REFERENCE TO PRIOR APPLICATION

This application claims the benefit of U.S. Provisional Patent Application Ser. No. 61/067,936, which was filed on Mar. 1, 2008, which is herein incorporated by reference.

### BACKGROUND OF THE INVENTION

Solid state lighting offers a significant advantage over incandescent and fluorescent light sources. A solid state light source has electricity pass through an active region of semiconductor material to emit light. Solid state light sources are typically light emitting diodes (LEDs). An incandescent light source has electricity pass through a filament, which emits light. A fluorescent light source is a gas discharge light where electricity excites mercury vapor, which emits ultraviolet light. The ultraviolet light strikes phosphors in the fluorescent light, which in turn emit visible light.

Solid state lighting still suffers from poor intensity control and poor color control. This poor intensity and color control of solid state lighting has forced the industry to use binning.

Many optical applications use multiple LEDs in a single device, but color and light intensity tolerance ranges for LEDs can be large and result in a non-uniform appearance, both within a single device and across multiple devices. To accommodate these wide color and intensity variations, LED manufacturers often sort each LED into a particular color and/or intensity “bin”, thereby minimizing variances within a selected LED group.

Generally, color and brightness uniformity of an LED array or LED panel is improved by selecting LEDs for specific locations on the array or panel. For example, the lower brightness LEDs would be placed at the ends of the rows, while the brighter LEDs would be placed in the middle part of the strip. Such binning of the LEDs may result in greater than a 15% difference in brightness levels for the same color LED.

Additionally, the array or panel's light emitting characteristics can be measured after placing of the LED, and the arrays are combined such that only arrays or panels with closely matching white points are used in a single backlight. This process is called grading. The process of using bin patterns and grading in an attempt to create boards with uniform light characteristics and achieve a target white point is costly and time consuming.

If a high-volume end user requires LEDs having the specific characteristics exhibited in one intensity and/or color bin, the LED manufacturer must produce a sufficient quantity of LEDs for that bin as a percentage of all of the LED dies produced for a target color. Tight bin tolerances cause the LEDs contained in that bin to constitute a small portion of the total LED yield. It may be necessary for the user to accept multiple adjacent bins to fulfill quantity requirements. This process tends to be expensive and impractical for large production quantities because shortages may occur if the bins meeting production criteria constitute a relatively small fraction of the LED manufacturer's overall production.

Binning leads to increased handling and testing and significant yield losses because not all bins are useful to the end customer. The need therefore exists for methods and articles that eliminate or reduce the number of bins to a manageable level.

A solid state light source based on a distributed array of light emitting diodes (LEDs) within a solid luminescent element has been disclosed by Zimmerman et al. in U.S. Pat. No. 7,285,791, commonly assigned as the present application and herein incorporated by reference. Electricity passes through an active region of semiconductor material to emit light in a light emitting diode. The solid luminescent element is a wavelength conversion chip. US Published Patent Applications 20080042153 and 20080149166, commonly assigned as the present application and herein incorporated by reference, teach wavelength conversion chips for use with light emitting diodes. A light emitting diode, such as those in US Published Patent Applications 20080182353 and 20080258165, commonly assigned as the present application and herein incorporated by reference, will emit light of a first wavelength and that first wavelength light will be converted into light of a second wavelength by the wavelength conversion chip.

As disclosed in Zimmerman et al. above, the use of a wavelength conversion chip can be fully characterized in color and intensity of converted light from the wavelength conversion and emitted light from the LED, prior to the attachment of the wavelength conversion chip to the light emitting diode (LED). This full chracterization of the color and intensity reduces the total variation of the color and/intensity by matching the appropriate wavelength conversion chip to the appropriate LED.

The need however still exists for further methods to adjust the color and intensity. The techniques of color balancing have been used extensively in avionic and automotive backlit panels. In this case, a substantially transparent plastic part is coated with a thin coating of white paint. Light sources are mounted such that they couple into the plastic part. These sources are then turned on and either manually or via machine white paint is added or removed until a uniform lighting distribution is obtained. Using this approach variation in light sources can be overcome.

### SUMMARY OF THE INVENTION

The color and/or intensity of the light from the light source can be controlled and balanced by a subtractive method by removing portions of the wavelength conversion material on the solid state light source. The subtractive method forms holes or grooves in the wavelength conversion element. Portions of the wavelength conversion element can be removed by means including, but not limited to, laser ablation, mechanical means, sandblasting, plasma etching, photochemical etching, chemical etching, RIE etching and ion beam milling of at least a portion of the solid wavelength conversion element.

Alternately, the color and/or intensity of the light from the light source can be controlled and balanced by an additive method by adding portions of wavelength conversion material to the wavelength conversion element on the solid state light source. The added wavelength conversion material forms bumps or ridges on top of the wavelength conversion element. The added wavelength conversion material can be the same or a different material from the wavelength conversion element. The additive material may include, but is not limited to, wavelength conversion materials including paints, glasses, ceramics, quantum dots, nanophosphors, confined ions, glazes, and liquids. The additive methods include spraying, evaporation, sputtering, painting, and spin coating.

### BRIEF DESCRIPTION OF THE DRAWINGS

FIG. 1 is a side view of a Prior Art LED with a powder phosphor coating.

FIG. 2 is a side view of a Prior Art LED with a wavelength conversion chip.

FIG. 3 is a side view of a LED with wavelength conversion chip with laser cut pits according to the present invention.

FIG. 4 is a side view of a LED with wavelength conversion chip with luminescent paint spot according to the present invention.

FIG. 5 is a side view of a layered wavelength conversion element according to the present invention.

FIG. 6 is a side view of an array of LEDs attached to a layered conversion element according to the present invention.

FIG. 7 is a side view of a lambertian emitter balanced using both sandblasting and plasma spray according to the present invention.

FIG. 8 is a side view of an isotropic light source balanced using laser removal and patterned reflective coatings according to the present invention.

FIG. 9 is a perspective view of an automated system to balance light sources using this approach according to the present invention.

### DETAILED DESCRIPTION OF DRAWINGS

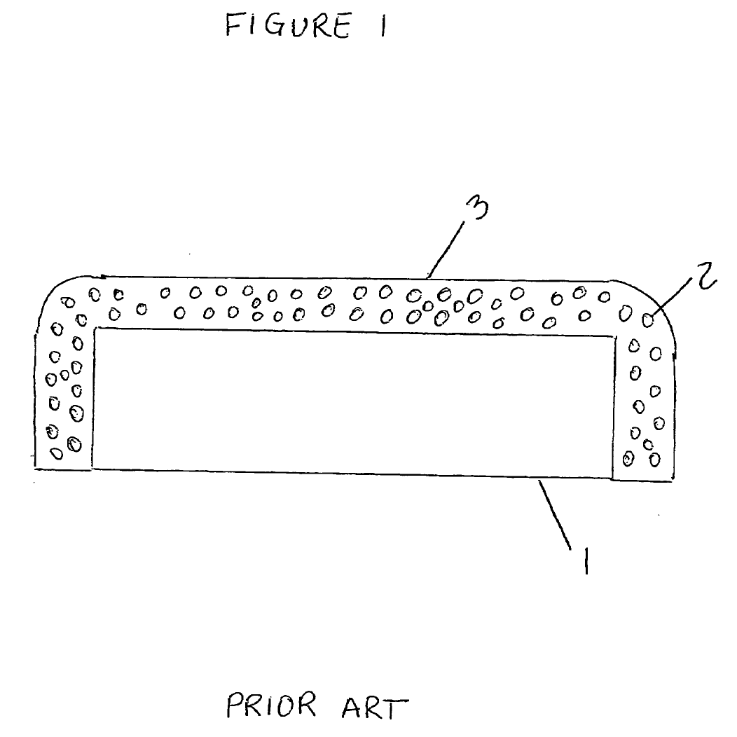

FIG. 1 depicts existing prior art in which a wavelength conversion element of a powdered phosphor 2 in an organic binder 3 is deposited by a variety of techniques onto a light emitting diode (LED) 1.

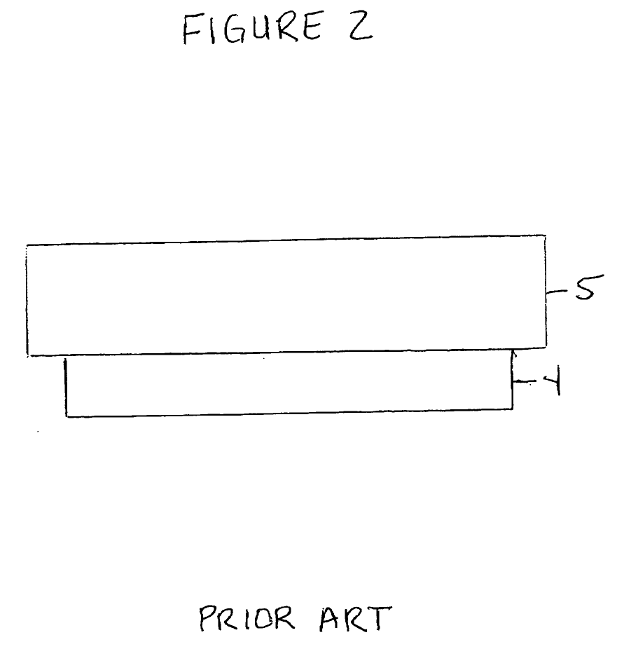

FIG. 2 depicts existing prior art in which a wavelength conversion element of a solid luminescent element 5 typically ceramic, single crystal or glass is attached directly or remotely to a LED 4.

The wavelength conversion element is formed from wavelength conversion materials. The wavelength conversion materials absorb light in a first wavelength range and emit light in a second wavelength range, where the light of a second wavelength range has longer wavelengths than the light of a first wavelength range. The wavelength conversion materials may be, for example, phosphor materials or quantum dot materials. The wavelength conversion element may be formed from two or more different wavelength conversion materials. The wavelength conversion element may also include optically inert host materials for the wavelength conversion materials of phosphors or quantum dots. Any optically inert host material must be transparent to ultraviolet and visible light.

Phosphor materials are typically optical inorganic materials doped with ions of lanthanide (rare earth) elements or, alternatively, ions such as chromium, titanium, vanadium, cobalt or neodymium. The lanthanide elements are lanthanum, cerium, praseodymium, neodymium, promethium, samarium, europium, gadolinium, terbium, dysprosium, holmium, erbium, thulium, ytterbium and lutetium. Optical inorganic materials include, but are not limited to, sapphire (Al.sub.2O.sub.3), gallium arsenide (GaAs), beryllium aluminum oxide (BeAl.sub.2O.sub.4), magnesium fluoride (MgF.sub.2), indium phosphide (InP), gallium phosphide (GaP), yttrium aluminum garnet (YAG or Y.sub.3Al.sub.5O.sub.12), terbium-containing garnet, yttrium-aluminum-lanthanide oxide compounds, yttrium-aluminum-lanthanide-gallium oxide compounds, yttrium oxide (Y.sub.2O.sub.3), calcium or strontium or barium halophosphates (Ca,Sr,Ba).sub.5(PO.sub.4).sub.3(Cl,F), the compound CeMgAl.sub.11O.sub.19, lanthanum phosphate (LaPO.sub.4), lanthanide pentaborate materials ((lanthanide)(Mg,Zn)B.sub.5O.sub.10), the compound BaMgAl.sub.10O.sub.17, the compound SrGa.sub.2S.sub.4, the compounds (Sr,Mg,Ca,Ba)(Ga,Al,In).sub.2S.sub.4, the compound SrS, the compound ZnS and nitridosilicate. There are several exemplary phosphors that can be excited at 250 nm or thereabouts. An exemplary red emitting phosphor is Y.sub.2O.sub.3:Eu.sup.3+. An exemplary yellow emitting phosphor is YAG:Ce.sup.3+. Exemplary green emitting phosphors include CeMgAl.sub.11O.sub.19:Tb.sup.3+, ((lanthanide)PO.sub.4:Ce.sup.3+,Tb.sup.3+) and GdMgB.sub.5O.sub.10:Ce.sup.3+,Tb.sup.3+. Exemplary blue emitting phosphors are BaMgAl.sub.10O.sub.17:Eu.sup.2+ and (Sr,Ba,Ca).sub.5(PO.sub.4).sub.3Cl:Eu.sup.2+. For longer wavelength LED excitation in the 400-450 nm wavelength region or thereabouts, exemplary optical inorganic materials include yttrium aluminum garnet (YAG or Y.sub.3Al.sub.5O.sub.12), terbium-containing garnet, yttrium oxide (Y.sub.2O.sub.3), YVO.sub.4, SrGa.sub.2S.sub.4, (Sr,Mg,Ca,Ba)(Ga,Al,In).sub.2S.sub.4, SrS, and nitridosilicate. Exemplary phosphors for LED excitation in the 400-450 nm wavelength region include YAG:Ce.sup.3+, YAG:Ho.sup.3+, YAG:Pr.sup.3+, YAG:Tb.sup.3+, YAG:Cr.sup.3+, YAG:Cr.sup.4+, SrGa.sub.2S.sub.4:Eu.sup.2+, SrGa.sub.2S.sub.4:Ce.sup.3+, SrS:Eu.sup.2+ and nitridosilicates doped with Eu.sup.2+.

Luminescent materials based on ZnO and its alloys with Mg, Cd, Al are preferred. More preferred are doped luminescent materials of ZnO and its alloys with Mg, Cd, Al which contain rare earths, Bi, Li, Zn, as well as other luminescent dopants. Even more preferred is the use of luminescent elements which are also electrically conductive, such a rare earth doped AlZnO, InZnO, GaZnO, InGaZnO, and other transparent conductive oxides of indium, tin, zinc, cadmium, aluminum, and gallium. Other phosphor materials not listed here are also within the scope of this invention.

Quantum dot materials are small particles of inorganic semiconductors having particle sizes less than about 30 nanometers. Exemplary quantum dot materials include, but are not limited to, small particles of CdS, CdSe, ZnSe, InAs, GaAs and GaN. Quantum dot materials can absorb light at first wavelength and then emit light at a second wavelength, where the second wavelength is longer than the first wavelength. The wavelength of the emitted light depends on the particle size, the particle surface properties, and the inorganic semiconductor material.

The transparent and optically inert host materials are especially useful to spatially separate quantum dots. Host materials include polymer materials and inorganic materials. The polymer materials include, but are not limited to, acrylates, polystyrene, polycarbonate, fluoroacrylates, chlorofluoroacrylates, perfluoroacrylates, fluorophosphinate polymers, fluorinated polyimides, polytetrafluoroethylene, fluorosilicones, sol-gels, epoxies, thermoplastics, thermosetting plastics and silicones. Fluorinated polymers are especially useful at ultraviolet wavelengths less than 400 nanometers and infrared wavelengths greater than 700 nanometers owing to their low light absorption in those wavelength ranges. Exemplary inorganic materials include, but are not limited to, silicon dioxide, optical glasses and chalcogenide glasses.

The solid state light source is typically a light emitting diode. Light emitting diodes (LEDs) can be fabricated by epitaxially growing multiple layers of semiconductors on a growth substrate. Inorganic light-emitting diodes can be fabricated from GaN-based semiconductor materials containing gallium nitride (GaN), aluminum nitride (AIN), aluminum gallium nitride (AlGaN), indium nitride (InN), indium gallium nitride (InGaN) and aluminum indium gallium nitride (AlInGaN). Other appropriate materials for LEDs include, for example, aluminum gallium indium phosphide (AlGaInP), gallium arsenide (GaAs), indium gallium arsenide (InGaAs), indium gallium arsenide phosphide (InGaAsP), diamond or zinc oxide (ZnO).

Especially important LEDs for this invention are GaN-based LEDs that emit light in the ultraviolet, blue, cyan and green regions of the optical spectrum. The growth substrate for GaN-based LEDs is typically sapphire (Al.sub.2O.sub.3), silicon carbide (SiC), bulk gallium nitride or bulk aluminum nitride.

A solid state light source can be a blue or ultraviolet emitting LED used in conjunction with one or more wavelength conversion materials such as phosphors or quantum dots that convert at least some of the blue or ultraviolet light to other wavelengths. For example, combining a yellow phosphor with a blue emitting LED can result in a white light source. The yellow phosphor converts a portion of the blue light into yellow light. Another portion of the blue light bypasses the yellow phosphor. The combination of blue and yellow light appears white to the human eye. Alternatively, combining a green phosphor and a red phosphor with a blue LED can also form a white light source. The green phosphor converts a first portion of the blue light into green light. The red phosphor converts a second portion of the blue light into green light. A third portion of the blue light bypasses the green and red phosphors. The combination of blue, green and red light appears white to the human eye. A third way to produce a white light source is to combine blue, green and red phosphors with an ultraviolet LED. The blue, green and red phosphors convert portions of the ultraviolet light into, respectively, blue, green and red light. The combination of the blue, green and red light appears white to the human eye.

The light source of the present invention is a solid wavelength conversion element on a solid state light source. The wavelength conversion element can be a luminescent element. The solid state light source can be a light emitting diode having an active region of, for example, a p-n homojunction, a p-n heterojunction, a double heterojunction, a single quantum well or a multiple quantum well of the appropriate semiconductor material for the LED. The solid state light source can also be a laser diode, a vertical cavity surface emitting laser (VCSEL), an edge-emitting light emitting diode (EELED), or an organic light emitting diode (OLED).

The solid state light source emits light of a first wavelength. The first wavelength light will be emitted through the wavelength conversion element 1. The wavelength conversion element will convert some of the light of a first wavelength into light of a second wavelength. The second wavelength is different from the first wavelength. The light of the second wavelength will be transmitted out of the wavelength conversion element. The remainder of the unconverted light of the first wavelength will also be transmitted out of the wavelength conversion element with the light of the second wavelength. The combination of light of the first wavelength with light of the second wavelength provides a broader emission spectrum of light from the light source having a combination of a solid state light source and a solid wavelength conversion element. The wavelength conversion element can be a luminescent element.

The color and/or intensity of the light from the light source can be controlled and balanced by a subtractive method by removing portions of the wavelength conversion material on the solid state light source. The subtractive method forms holes or grooves in the wavelength conversion element. Alternately, the color and/or intensity of the light from the light source can be controlled and balanced by an additive method by adding portions of wavelength conversion material to the wavelength conversion element on the solid state light source. The added wavelength conversion material forms bumps or ridges on top of the wavelength conversion element. The added wavelength conversion material can be the same or a different material from the wavelength conversion element.

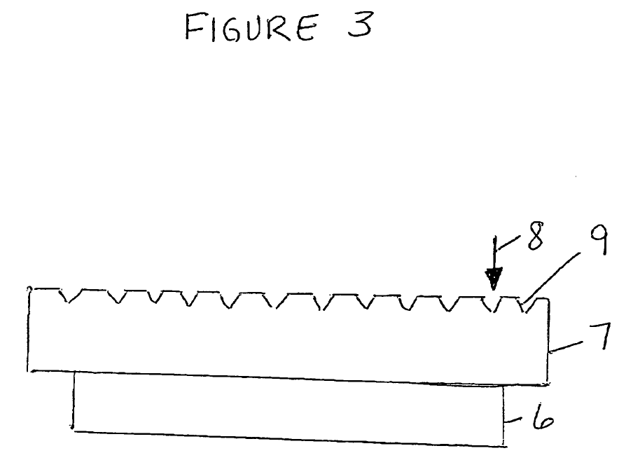

FIG. 3 depicts a solid wavelength conversion element 7 attached to a LED 6 in which some of the material in solid wavelength conversion element 7 is removed using laser energy 8 to form holes 9. The location and number of holes 9 is adjusted to create a particular color and/or intensity distribution across the wavelength conversion element. This can based on either near field or far field measurements depending on the desired result.

Portions of the solid wavelength conversion element can be removed by means including, but not limited to, laser ablation, mechanical means, sandblasting, plasma etching, photochemical etching, chemical etching, RIE etching and ion beam milling of at least a portion of the solid wavelength conversion element.

The holes can be in ordered pattern or a random pattern in the wavelength conversion element. The holes can be any geometric or non-geometric shape. The holes do not have to be all the same shape. The holes can vary in depth and/or size or have uniform depth and/or size. Instead of holes, grooves can be formed in the wavelength conversion element.

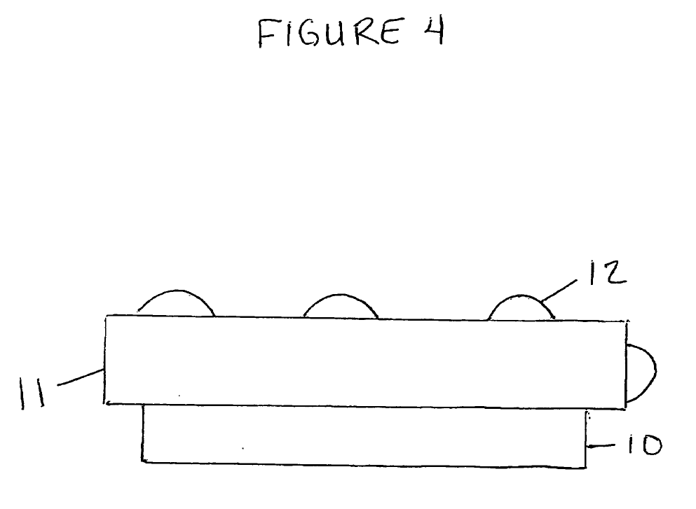

FIG. 4 depicts a solid wavelength conversion element 11 attached to a LED 10 in which an additive element 12 is deposited or otherwise attached to solid wavelength conversion element 11. Additive element 12 may include, but is not limited to, wavelength conversion materials including paints, glasses, ceramics, quantum dots, nanophosphors, confined ions, glazes, and liquids. The use of methods such as spraying, evaporation, sputtering, painting, and spin coating as known in the art are all embodiments of this invention. The added wavelength conversion material forms bumps or ridges on top of the wavelength conversion element. The added wavelength conversion material can be the same or a different material from the wavelength conversion element. The bumps can be in ordered pattern or a random pattern on the wavelength conversion element. The bumps can be any geometric or non-geometric shape. The bumps do not have to be all the same shape. The bumps can vary in height and/or size or have uniform height and/or size. Instead of bumps, ridges can be formed in the wavelength conversion element.

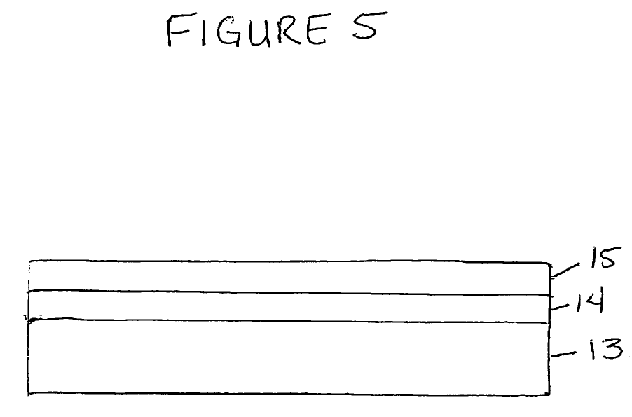

FIG. 5 depicts a layered solid wavelength conversion element consisting of a substantially transparent layer 13 and at least one wavelength conversion layer either 14 or 15. More preferably, two or more layers can exhibit the same or different wavelength conversion characteristics. These layers can be formed via consolidation of tape casting, spray coating, evaporative coatings, melt bonding, sol-gel coating, fusion bonding, and glazing methods as known in the art. The materials exhibiting high thermal conductivity can be used such as but not limited to YAG, glass, diamond, ZnO, AIN, GaN, and sapphire. Quantum dots and wavelength conversion flakes or particles can be incorporated within the various layers. Wavelength shifting structures such as photonic crystals can modify the color of the layer and the formation of photonic structures to restrict angular output distribution.

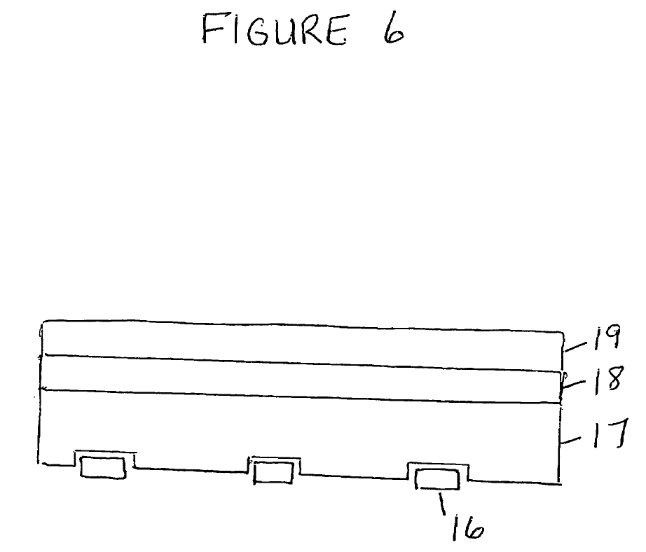

FIG. 6 depicts an array LED light source containing at least one LED 16, a substantially transparent layer 17 and at least one wavelength conversion layer either 18 or 19. More preferably, two or more layers can exhibit the same or different wavelength conversion characteristics. The at least one LED 16, may be attached via organic or inorganic means. In addition, embedding techniques can be used, such as co-sintering, sol-gel curing, use of molten glasses in which die can be embedded, and recessed pockets with either a filler or compression fit.

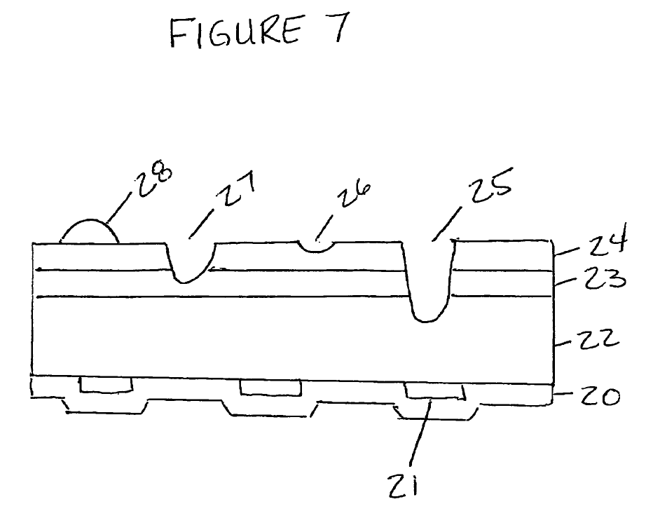

FIG. 7 depicts a lambertian light source containing at least one LED 21 and a reflective layer 20 which may consist but not limited to a reflective metal coating, an enhanced reflective coating such as an ODR, a dielectric reflective coating with or without substantial angular variation either in reflectance as a function of wavelength. The dielectric reflective coating can narrow, distribute, or direct the light from at least one LED 21. The reflective layer 20 may cover all or part of the light source and can be used to enhance brightness by forming a recycling light cavity. The at least one LED 21 and reflective layer 20 are attached to substantially transparent layers 20 and at least one wavelength conversion layer 23 or 24. More preferably, two or more layers exhibiting the same or different wavelength conversion characteristic are also disclosed. The removal of all or part of the wavelength conversion layers via sandblasting is depicted in holes 25, 26, and 27. The location and amount of the material being removed is dependent on the desired color and intensity distribution. The use of additive elements 28 as described previously in FIG. 4 are also an embodiment of this invention.

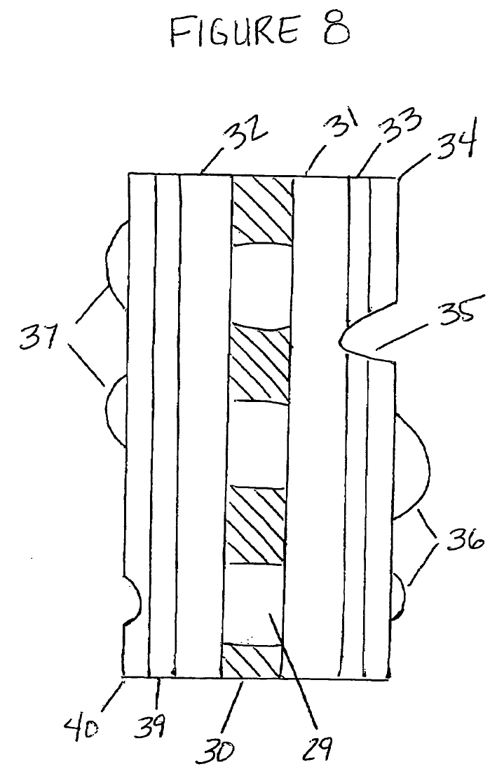

FIG. 8 depicts a substantially isotropic light source consisting of at least one LED 29 embedded in matrix 30 and sandwiched between substantially transparent layers 31 and 32. While the use of substantially transparent layers 31 and 32 are preferred for enhancing light spreading from at least one LED 29, a substantially isotropic light source consisting of at least one LED 29 embedded between two substantially wavelength conversion layers is also an embodiment of this invention. The removal of wavelength conversion layers 33 and 34 on one side and 40 and 39 on the other side via laser cutting to form holes 35 and 38 are shown. Patterned reflectors 36 and 37 are also formed. Due to the transmissive nature of this light source, light reflective back can be used to modify the other side of the light source rather than using absorptive means. The use of dichroic, reflective polarizers, or other partially reflecting elements to create a particular output distribution or effect are disclosed.

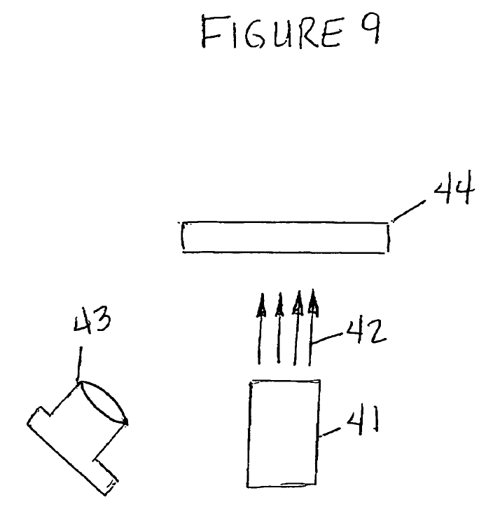

FIG. 9 depicts an automated color and intensity balancing apparatus consisting of the light source disclosed 44, a meter 43, a delivery system 41, and a subtractive or additive means 42 which is used to modify the color and/or intensity of the light source disclosed 44. The meter 43 may include photometer, radiometer, and any light meter with or without ability to discern color changes. The use of a photometer based on variable bandpass CCD array is preferred. The meter 43 shall have sufficient spatial resolution to control the delivery system 41 such that subtractive and additive means 42can be accurately placed on the light source disclosed 44. The delivery system 41 maybe include but not limited to inkjet printing, laser scribing (both galvo based and mechanical stage based), manual methods (such as painting, screen printing, and airbrush), and etching means including sandblasting, chemical etching, reactive ion etching, and other subtractive means including the use of lithographic methods known in the art. The meter 43 maybe used to provide feedback to the delivery system 41 via electronic, optical and manual means.

The wavelength conversion material can be layered luminescent and non-luminescent ceramic and glass materials. Multiple types of luminescent materials can be incorporated into the wavelength conversion element either within a single layer or as separate layers or as spatially distributed regions within a layer.

The use of internal and surface scatter in any of the layers is also an embodiment of this invention. A light spreading layer can further balance the intensity from localized point sources. This light spreading layer can be inorganic or organic in nature but substantially transparent to emission from the light sources being used. The inclusion of electrical interconnect means into the wavelength conversion element allows for excitation of light emitting elements.

While the invention has been described with the inclusion of specific embodiments and examples, it is evident to those skilled in the art that many alternatives, modifications and variations will be evident in light of the foregoing descriptions. Accordingly, the invention is intended to embrace all such alternatives, modifications and variations that fall within the spirit and scope of the appended claims.

1. A subtractive method of balancing color and intensity of a light emitted from a light source comprising
forming a light source of a solid wavelength conversion element on a solid state light source, and
removing portions of said solid wavelength conversion element.

2. The subtractive method of balancing color and intensity of a light emitted from a light source of claim 1 wherein said solid state light source is a light emitting diode.

3. The subtractive method of balancing color and intensity of a light emitted from a light source of claim 1 wherein said removing portions of said solid wavelength conversion element forms at least one hole in said solid wavelength conversion element.

4. The subtractive method of balancing color and intensity of a light emitted from a light source of claim 1 wherein said removing portions of said solid wavelength conversion element forms at least one groove in said solid wavelength conversion element.

5. The subtractive method of balancing color and intensity of a light emitted from a light source of claim 1 wherein said removing portions of said solid wavelength conversion element is by means including, but not limited to, laser ablation, mechanical means, sandblasting, plasma etching, photochemical etching, chemical etching, RIE etching and ion beam milling of at least a portion of said solid wavelength conversion element.

6. The subtractive method of balancing color and intensity of a light emitted from a light source of claim 1 further comprising
adding portions of a solid wavelength conversion material to said solid wavelength conversion element.

7. The subtractive method of balancing color and intensity of a light emitted from a light source of claim 1 wherein said solid wavelength conversion element is a luminescent element.

8. An additive method of balancing color and intensity of a light emitted from a light source comprising
forming a light source of a solid wavelength conversion element on a solid state light source, and
adding portions of a solid wavelength conversion material to said solid wavelength conversion element.

9. The additive method of balancing color and intensity of a light emitted from a light source of claim 8 wherein said solid state light source is a light emitting diode.

10. The additive method of balancing color and intensity of a light emitted from a light source of claim 8 wherein said adding portions of said solid wavelength conversion element forms at least one bump on said solid wavelength conversion element.

11. The additive method of balancing color and intensity of a light emitted from a light source of claim 8 wherein said removing portions of said solid wavelength conversion element forms at least one ridge on said solid wavelength conversion element.

12. The additive method of balancing color and intensity of a light emitted from a light source of claim 8 wherein said portions of a solid wavelength conversion material are the same material as said solid wavelength conversion element.

13. The additive method of balancing color and intensity of a light emitted from a light source of claim 8 wherein said portions of a solid wavelength conversion material are a different material as said solid wavelength conversion element.

14. The additive method of balancing color and intensity of a light emitted from a light source of claim 8 wherein said adding portions of a solid wavelength conversion material to said solid wavelength conversion element is by means including, but not limited to, thick film processing, glazing, sol-gel, melt bonding, spraying, evaporation, spin coating, and painting onto at least a portion of said solid wavelength conversion element.

15. The additive method of balancing color and intensity of a light emitted from a light source of claim 8 wherein said solid wavelength conversion element is a luminescent element.
